(19) United States
(12) Patent Application Publication
(10) Pub. No.: US 2026/0353979 A1
(43) Pub. Date: Nov. 5, 2026

(54) DISPLAY PANEL, METHOD FOR MANUFACTURING THE DISPLAY PANEL, AND ELECTRONIC DEVICE INCLUDING THE DISPLAY PANEL

(71) Applicant: Samsung Display Co., Ltd., Yongin-si (KR)

(72) Inventors: Areum LEE, Yongin-si (KR); Jungsun PARK, Yongin-si (KR); Joongu LEE, Yongin-si (KR)

(73) Assignee: Samsung Display Co., Ltd., Yongin-si (KR)

(21) Appl. No.: 19/645,806

(22) Filed: Apr. 13, 2026

(30) Foreign Application Priority Data
May 2, 2025 (KR) 10-2025-0057950

(51) Int. Cl. H10K 59/80; H10K 59/12; H10K 102/00; H10K 102/10

(52) U.S. Cl. CPC H10K 59/80524; H10K 59/1201; H10K 59/80521; H10K 59/873; H10K 2102/10; H10K 2102/351

(57) ABSTRACT

A display panel according to the inventive concepts may include a base layer, and a display element layer on the base layer, the display element layer comprising a first electrode, an emission layer on the first electrode, a second electrode on the emission layer, and a functional layer on the second electrode. The functional layer comprises titanium nitride (TiN) and has a thickness greater than or equal to 2 nm and less than or equal to 6 nm, and the second electrode has a thickness greater than or equal to 3 nm and less than or equal to 5 nm.

### CROSS-REFERENCE TO RELATED APPLICATIONS

This U.S. non-provisional patent application claims priority under 35 U.S.C. § 119 of Korean Patent Application No. 10-2025-0057950, filed on May 2, 2025, the entire contents of which are hereby incorporated by reference.

### BACKGROUND

Example embodiments of the present disclosure herein relate to a display panel and an electronic device including the same, and more particularly, to a display panel with an improved viewing angle and an electronic device including the display panel.

Display devices such as televisions, monitors, smartphones, and tablet computers, which provide images for users, may include display panels which display images. Various display panels such as liquid crystal display panels, organic light emitting display panels, electro wetting display panels, and electrophoretic display panels, are being developed. However, displayed images may change depending on an angle at which a user views a display panel.

### SUMMARY

Some example embodiments of the present disclosure provide a display panel with an improved viewing angle and a method for manufacturing the display panel.

Some example embodiments of the inventive concepts provide a display panel including a base layer, and a display element layer on the base layer, the display element layer comprising a first electrode, an emission layer on the first electrode, a second electrode on the emission layer, and a functional layer on the second electrode. The functional layer comprises titanium nitride (TiN) and has a thickness greater than or equal to 2 nm and less than or equal to 6 nm, and the second electrode has a thickness greater than or equal to 3 nm and less than or equal to 5 nm.

In some example embodiments of the inventive concepts, a method for manufacturing a display panel includes providing a preliminary display panel comprising a base layer, a first electrode on the base layer, an emission layer on the first electrode, and a second electrode on the emission layer, the second electrode having a thickness of greater than or equal to 3 nm and less than or equal to 5 nm, forming a functional layer on the second electrode, the functional layer comprising titanium nitride (TiN) and having a thickness greater than or equal to 2 nm and less than or equal to 6 nm; and forming a capping layer on the functional layer.

In some example embodiments of the inventive concepts, an electronic device includes a processor configured to provide image data, and a display panel connected to the processor. The display panel comprises a base layer, and a display element layer on the base layer, the display element layer comprising a first electrode, an emission layer on the first electrode, a second electrode on the emission layer, and a functional layer on the second electrode. The functional layer comprises titanium nitride (TiN) and has a thickness of greater than or equal to 2 nm and less than or equal to 6 nm. and the second electrode has a thickness of greater than or equal to 3 nm and less than or equal to 5 nm.

In some example embodiments, the functional layer may be directly disposed on the second electrode and have an electrically conductive property, and a capping layer directly disposed on the functional layer may be further included.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a block diagram of an electronic device according to the some example embodiments of the inventive concepts;

FIG. 2 is a schematic view of electronic devices according to some example embodiments of the example embodiments;

FIG. 3 is a perspective view of an electronic device according to some example embodiments of the inventive concepts;

FIG. 4 is an exploded perspective view of an electronic device according to some example embodiments of the inventive concepts;

FIG. 5A is a cross-sectional view of a display module according to some example embodiments of the inventive concepts;

FIG. 5B is a cross-sectional view of a display panel according to some example embodiments of the inventive concepts;

FIG. 6 is a cross-sectional view of a display panel according to some example embodiments of the inventive concepts;

FIG. 7 is an enlarged view of area AA′ in FIG. 6;

FIG. 8 is photographs showing film formation reliability of functional layers according to some example embodiments of the inventive concepts and a comparative example;

FIG. 9 is a graph illustrating experimental data according to some example embodiments of the inventive concepts;

FIG. 10 is a graph illustrating experimental data according to some example embodiments of the inventive concepts;

FIG. 11 is a graph illustrating experimental data according to some example embodiments of the inventive concepts;

FIG. 12 is a flowchart of a method for manufacturing a display panel according to some example embodiments of the inventive concepts; and

FIGS. 13 to 18 are each a view illustrating a step of a method for manufacturing a display panel according to some example embodiments of the inventive concepts.

### DETAILED DESCRIPTION

Some example embodiments of the inventive concepts may be modified in various forms, and particular example embodiments thereof will be illustrated in the drawings and described herein in detail. However, the inventive concepts should not be construed as limited to the example embodiments set forth herein. Rather, these example embodiments are provided so that this disclosure will be thorough and complete, and will fully convey the scope of the inventive concepts to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concepts. Similarly, a second element could be termed a first element. In this specification, the singular expressions “a”, “an,” and “the” are intended to include the plural forms as well, unless the context clearly indicates otherwise.

In addition, the terms “below”, “under”, “on the lower side”, “above”, “over” “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the inventive concepts are described with reference to the accompanying drawings.

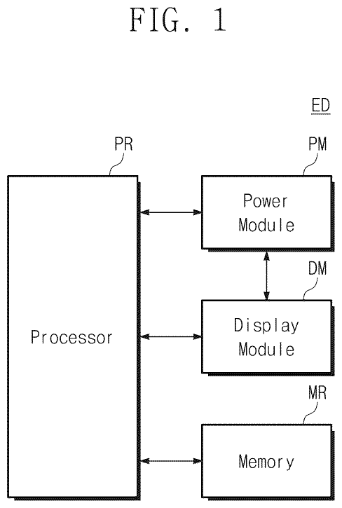

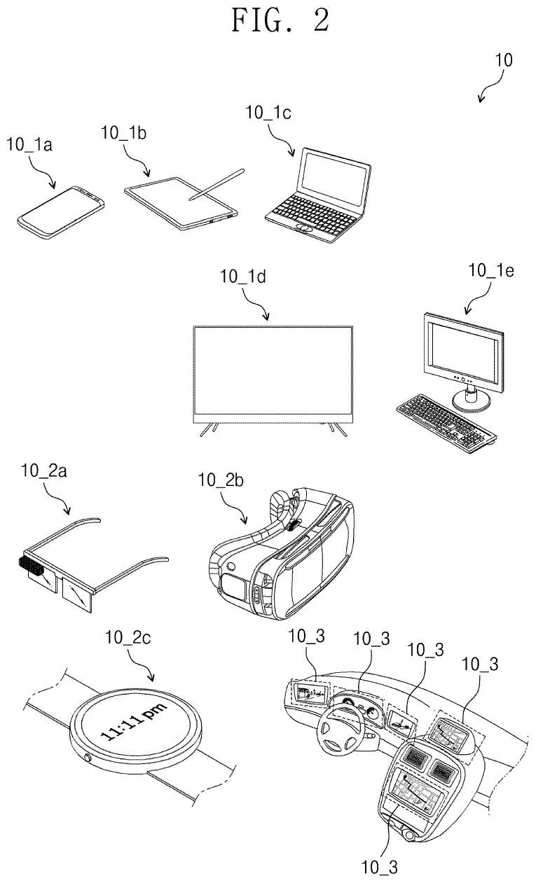

FIG. 1 is a block diagram of an electronic device according to some example embodiments of the inventive concepts. FIG. 2 is a schematic view of electronic devices according to some example embodiments of the example embodiments.

FIG. 1 is a block diagram of an electronic device according to some example embodiments of the inventive concepts.

The electronic device according to some example embodiments of the inventive concepts may be provided in various types. The electronic device according to some example embodiments of the inventive concepts may further include a module or device having another additional function.

Referring to FIG. 1, an electronic device ED according to some example embodiments may include a display module DM, a processor PR, a memory MR, and a power module PM.

The processor PR may provide image data. The processor PR may include at least one of a central processing unit (CPU), an application processor (AP), a graphic processing unit (GPU), a communication processor (CP), an image signal processor (ISP), or a controller.

The memory MR may store data information for an operation of the processor PR or the display module DM. When the processor PR executes an application stored in the memory MR, an image data signal and/or an input control signal may be transmitted to the display module DM, and the display module DM may process the received signal and output image information through a display screen.

The power module PM may include a power supply module such as a power adapter or a battery device, and a power conversion module which converts the power supplied by the power supply module and generates power for an operation of the electronic device ED.

Some individual modules included as functional in one module may be included in the display module DM, and others may be provided in the electronic device ED separately from the display module DM.

FIG. 2 is a schematic view of electronic devices according to some example embodiments.

Referring to FIG. 2, electronic devices according to some example embodiments may include not only an electronic device for image display, e.g., a smartphone ED_1a, a tablet PC ED_1b, a laptop computer ED_1c, TV ED_1d, and a monitor for a desk computer ED_1e, but also a wearable electronic device including a display module, e.g., smart glasses ED_2a, a head mounted display ED_2b, and a smartwatch ED_2c, and a vehicle electronic device ED_3 including a display module, e.g., a vehicle instrument panel, a center fascia, a center information display (CID) disposed on a dashboard, and a room mirror display.

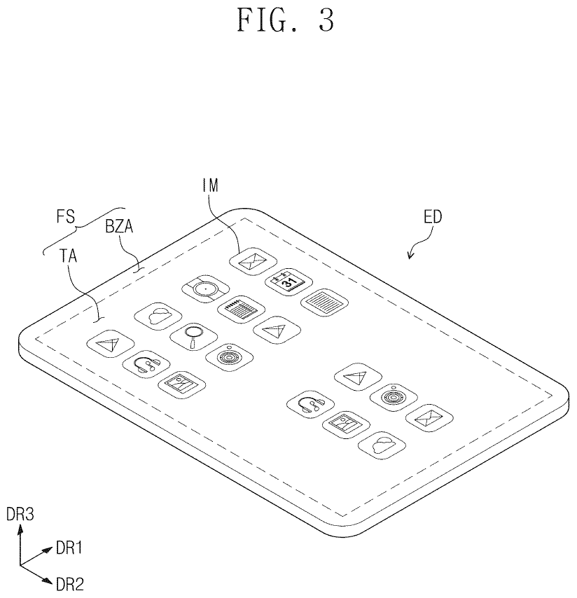

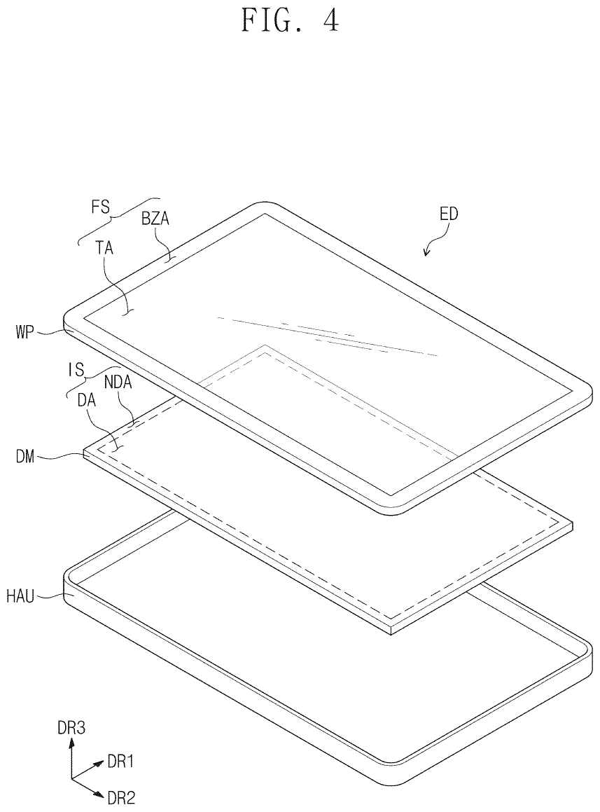

FIG. 3 is a perspective view of an electronic device according to some example embodiments of the inventive concepts. FIG. 4 is an exploded perspective view of an electronic device according to some example embodiments of the inventive concepts.

In some example embodiments, the electronic device ED may have a rectangular shape having short sides extending in a first direction DR1 and having long sides extending in a second direction DR2 on a plane. However, example embodiments of the inventive concepts are not limited thereto, and the electronic device ED may have various shapes such as a circular shape or a polygonal shape.

The electronic device ED may display an image IM in a third direction DR3 through a display surface FS parallel to a plane defined by the first direction DR1 and the second direction DR2. The third direction DR3 may be substantially parallel to a normal direction to the display surface FS. The display surface FS on which the image IM is displayed may correspond to a front surface of the electronic device ED. The image IM may include not only a dynamic image but also a still image. FIG. 3 illustrates icon images as an example of the image IM.

In some example embodiments, a front surface (or top surface) and a rear surface (or bottom surface) of each members or units may be defined on the basis of a direction in which the image IM is displayed. The front surface and the rear surface may oppose each other in the third direction DR3, and a normal direction to each of the front surface and the rear surface may be parallel to the third direction DR3. A separation distance between the front surface and the rear surface, which is defined along the third direction DR3, may correspond to a thickness of a member (or unit).

The term “on a plane” used herein may be defined as being in a state when viewed in the third direction DR3. The term “on a cross-section” used herein may be defined as being in a state when viewed in the first direction DR1 or the second direction DR2. However, directions indicated by the first to third directions DR1, DR2 and DR3 are relative concepts and may be changed to other directions.

In the electronic device ED, the display surface FS on which the image IM is displayed may correspond to the front surface of the electronic device ED and may correspond to a front surface FS of a window WP (see FIG. 4). Hereinafter, the display surface and the front surface of the electronic device ED and the front surface of the window WP are designated by the like reference symbol. However, although not illustrated in the drawing, the electronic device ED may include a foldable display device including a folding area and a non-folding area, a bendable display device including at least one bending portion, or the like.

Referring to FIG. 4, the electronic device ED according to some example embodiments may include the window WP, a display module DM, and a housing HAU.

The window WP may include an optically transparent insulating material. The window WP may include a transmission area TA and a bezel area BZA. An image provided through the transmission area TA corresponding to the front surface FS of the window WP may be visible to a user.

The transmission area TA may be an optically transparent area. The bezel area BZA may be an area having a relatively lower light transmittance when compared to the transmission area TA. The bezel area BZA may have a certain color. The bezel area BZA may be adjacent to the transmission area TA and surround the transmission area TA. The bezel area BZA may define a shape of the transmission area TA. However, example embodiments are not limited to the illustrated example embodiments, and the bezel area BZA may be disposed adjacent to only one side of the transmission area TA or a portion thereof may be omitted.

FIGS. 3 and 4 illustrate the transmission area TA having a rectangular shape. However, this is illustrated as an example, and the transmission area TA may have various shapes and is not limited to any one example embodiment.

The display module DM may be disposed below the window WP. The display module DM may be a component which substantially generates the image IM. The image IM generated by the display module DM is displayed on a display surface IS and is externally visible to a user through the transmission area TA.

The display module DM includes a display area DA and a non-display area NDA. The display area DA may be an area which is activated in response to an electrical signal. The non-display area NDA may be an area which is covered by the bezel area BZA. The non-display area NDA is adjacent to the display area DA. The non-display area NDA may surround the display area DA.

The housing HAU may accommodate the display module DM. The housing HAU may provide a base space in which the display module DM is disposed. The housing HAU may be arranged while covering the display module DM so that a top surface that is the display surface IS of the electronic device ED is exposed. The housing HAU may cover a side surface and a bottom surface of the display module DM and expose the entirety of a top surface thereof. However, example embodiments are not limited thereto, and the housing HAU may cover not only the side surface and the bottom surface of the display module DM but also a portion of the top surface.

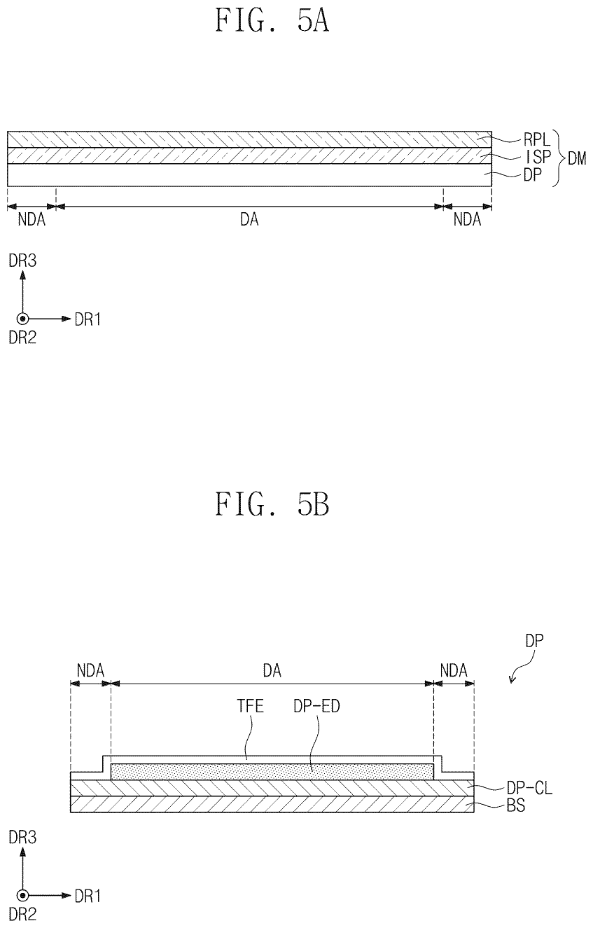

FIG. 5A is a cross-sectional view of a display module according to some example embodiments of the inventive concepts. FIG. 5B is a cross-sectional view of a display panel according to some example embodiments of the inventive concepts.

Referring to FIG. 5A, a display module DM may include a display panel DP, an input sensing part ISP, and an anti-reflective layer RPL. However, example embodiments of the inventive concepts are not limited thereto. For example, the input sensing part ISP or the anti-reflective layer RPL may be omitted.

The display panel DP in FIG. 5A may be an emissive display panel and is not particularly limited. For example, the display panel DP may be an organic light emitting display panel or an inorganic light emitting display panel. An emission layer of the organic light emitting display panel may include an organic light emitting material. An emission layer of the inorganic light emitting display panel may include a quantum dot, a quantum rod, and the like. Hereinafter, the display panel DP is described as the organic light emitting display panel.

The input sensing part ISP may be disposed on the display panel DP. The input sensing part ISP may include a plurality of sensors (not illustrated) for sensing an external input by using a capacitance method. The input sensing part ISP may be directly manufactured on the display panel DP during the manufacture of the display module DM. However, some example embodiments of the inventive concepts are not limited thereto, and the input sensing part ISP may be manufactured as a separate panel from the display panel DP and be attached to the display panel DP through an adhesive layer.

The anti-reflective layer RPL may be disposed on the input sensing part ISP. The anti-reflective layer RPL may be directly provided on the input sensing part ISP or be coupled to the input sensing part ISP through an adhesive layer. The anti-reflective layer RPL may be defined as a film which reduces or prevents the reflection of external light. The anti-reflective layer RPL may reduce the reflectance of external light incident from above the electronic device ED toward the display panel DP.

The window WP may be disposed on the anti-reflective layer RPL. The window WP may be directly provided on the anti-reflective layer WP or be coupled to the anti-reflective layer WP through an adhesive layer. The window WP may protect the display panel DP, the input sensing part ISP, and the anti-reflective layer RPL from external scratches and impact.

Referring to FIG. 5B, a display panel DP may include a base layer BS, a circuit element layer DP-CL disposed on the base layer BS, a display element layer DP-ED disposed on the circuit element layer DP-CL, and an encapsulation layer TFE disposed on the display element layer DP-ED.

The base layer BS may include a display area DA and a non-display area NDA around the display area DA. The base layer BS may include glass or a flexible plastic material such as polyimide (PI). The display element layer DP-ED may be disposed on the display area DA.

Pixels may be disposed in the circuit element layer DP-CL and the display element layer DP-ED. Each of the pixels may include a driving circuit including a transistor disposed in the circuit element layer DP-CL, and a light emitting element disposed in the display element layer DP-ED and connected to the transistor.

The encapsulation layer TFE may cover the display element layer DP-ED. The encapsulation layer TFE may protect the pixels from moisture, oxygen, and external foreign matter.

Referring to FIG. 5B, the display panel DP according to some example embodiments of the inventive concepts may include the base layer BS, the circuit element layer DP-CL disposed on the base layer BS, the display element layer DP-ED disposed on the circuit element layer DP-CL, and the encapsulation layer TFE disposed on the display element layer DP-ED.

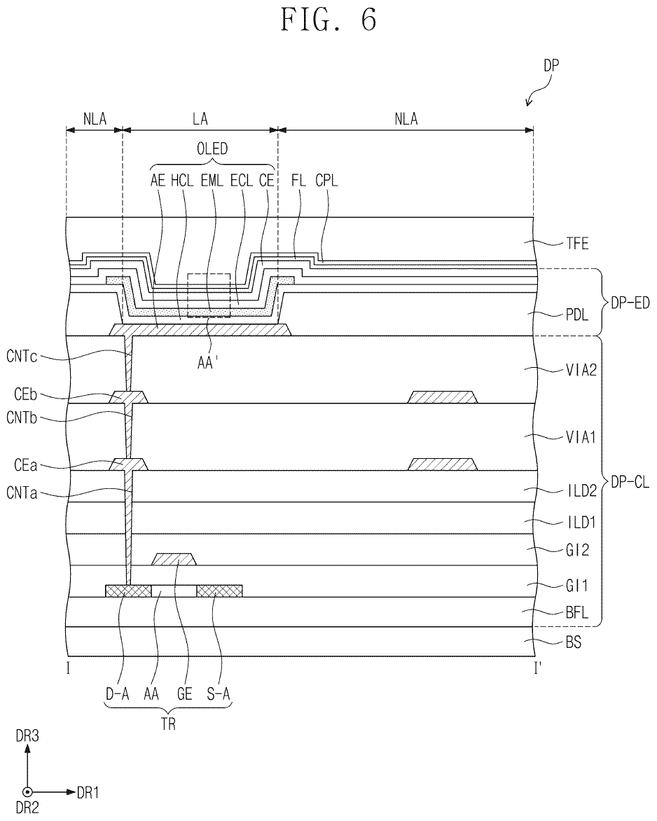

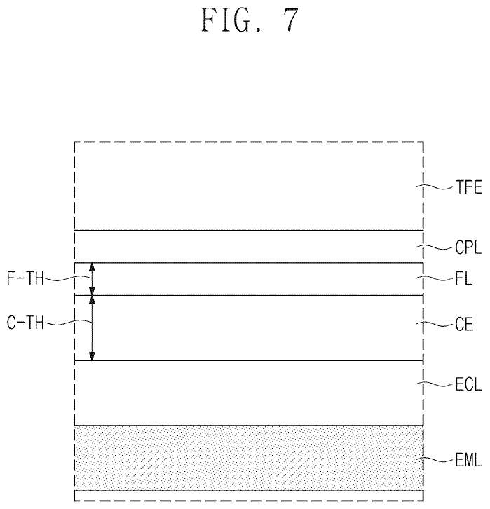

FIG. 6 is a cross-sectional view of a display panel according to some example embodiments of the inventive concepts. FIG. 7 is an enlarged view of area AA′ in FIG. 6.

Referring to FIG. 6, a display panel DP may include a base layer BS, a circuit element layer DP-CL, a display element layer DP-ED, and an encapsulation layer TFE.

The display panel DP may include an emission area LA and a non-emission area NLA. The emission area LA may be an area from which light provided from a light emitting element OLED is emitted. The display panel DP may include a plurality of insulating layers, a semiconductor pattern, a conductive pattern, a signal line, and the like.

The semiconductor pattern, the conductive pattern, the signal line, and the like which are included in the circuit element layer DP-CL and the display element layer DP-ED may be formed by forming the insulating layers, a semiconductor layer, and a conductive layer through a method such as coating or deposition and selectively patterning the insulating layers, the semiconductor layer, and the conductive layer through photolithography and etching.

The circuit element layer DP-CL may include pixel driving parts, a buffer layer BFL, and a plurality of insulating layers GI1, GI2, ILD1, ILD2, VIA1 and VIA2 stacked in sequence. Although FIG. 6 illustrates some example embodiments in which six insulating layers are included, this is illustrative and example embodiments of the inventive concepts are not limited thereto.

In FIG. 6, one transistor TR and connection electrodes CEa and CEb among the pixel driving parts are illustrated as an example for convenience of description. However, this is illustrated as an example, and the configuration and the arrangement relationship of the pixel driving parts constituting the circuit element layer DP-CL may be variously changed and are not limited to any one embodiment.

The buffer layer BFL may be disposed on the base layer BS. The buffer layer BFL may improve a bonding force between the base layer BS and the semiconductor pattern. The buffer layer BFL may include a silicon oxide layer and/or a silicon nitride layer.

A first insulating layer GI1 may be disposed on the buffer layer BFL. The first insulating layer GI1 may be an inorganic layer and/or an organic layer and have a single-layer or multilayer structure.

A second insulating layer GI2 may be disposed on the first insulating layer GI1. The second insulating layer GI2 may be an inorganic layer and/or an organic layer and have a single-layer or multilayer structure. The second insulating layer GI2 may include silicon nitride.

A third insulating layer ILD1 may be disposed on the second insulating layer GI2. The third insulating layer ILD1 may be an inorganic layer and/or an organic layer and have a single-layer or multilayer structure. The third insulating layer ILD1 may include the same material as the second insulating layer GI2. The third insulating layer ILD1 may include silicon nitride.

A fourth insulating layer ILD2 may be disposed on the third insulating layer ILD1. The fourth insulating layer ILD2 may be an inorganic layer and/or an organic layer and have a single-layer or multilayer structure. The fourth insulating layer ILD2 may include at least one of aluminum oxide, titanium oxide, silicon oxide, silicon nitride, silicon oxynitride, zirconium oxide, or hafnium oxide. However, example embodiments are not limited thereto.

A first connection electrode CEa may be disposed on the fourth insulating layer ILD2. The first connection electrode CEa may be connected to a drain region D-A of the transistor TR through a contact hole CNTa passing through the first to fourth insulating layers GI1, GI2, ILD1 and ILD2. However, example embodiments are not limited thereto, and the first connection electrode CEa may be connected to a source region S-A of the transistor TR through the contact hole CNTa. The transistor TR may be connected to the light emitting element OLED through the first connection electrode CEa.

A fifth insulating layer VIA1 which covers the first connection electrode CEa may be disposed on the fourth insulating layer ILD2. The fifth insulating layer VIA1 may be an inorganic layer and/or an organic layer and have a single-layer or multilayer structure. The fifth insulating layer VIA1 may include at least one of aluminum oxide, titanium oxide, silicon oxide, silicon nitride, silicon oxynitride, zirconium oxide, or hafnium oxide. However, example embodiments are not limited thereto.

A second connection electrode CEb may be disposed on the fifth insulating layer VIA1. The second connection electrode CEb may be connected to the first connection electrode CEa through a contact hole CNTb passing through the fifth insulating layer VIA1.

A sixth insulating layer VIA2 which covers the second connection electrode CEb may be disposed on the fifth insulating layer VIA1. The sixth insulating layer VIA2 may be an inorganic layer and/or an organic layer and have a single-layer or multilayer structure. The sixth insulating layer VIA2 may include at least one of aluminum oxide, titanium oxide, silicon oxide, silicon nitride, silicon oxynitride, zirconium oxide, or hafnium oxide. However, example embodiments are not limited thereto.

The display element layer DP-ED may include a pixel defining film PDL, the light emitting element OLED, a functional layer FL disposed on a second electrode CE, and a capping layer CPL disposed on the functional layer FL.

The light emitting element OLED may include a first electrode AE, an emission layer EML disposed on the first electrode AE, the second electrode CE disposed on the emission layer EML, a hole control layer HCL disposed between the first electrode AE and the emission layer EML, and an electron control layer ECL disposed between the second electrode CE and the emission layer EML.

The pixel defining film PDL may be disposed on the sixth insulating layer VIA2. An emission opening portion PDL-OP may be defined in the pixel defining film PDL. The pixel defining film PDL may cover a portion of the first electrode AE.

The first electrode AE may be disposed on the sixth insulating layer VIA2. The first electrode AE may be exposed through the emission opening portion PDL-OP. The pixel defining film PDL may include an inorganic insulating material. For example, the pixel defining film PDL may include silicon nitride.

The encapsulation layer TFE may be disposed on the light emitting element OLED. The encapsulation layer TFE may include an inorganic layer, an organic layer, and an inorganic layer which are stacked in sequence. The inorganic layers may include an inorganic material and protect the pixels from moisture/oxygen. The organic layer may include an organic material and protect the pixels PX from foreign matter such as dust particles. The second electrode CE may have a thickness C-TH of about 3 nm to about 5 nm.

The second electrode CE may be provided as a common layer, such that the second electrode CE is shared amongst each light emitting element OLED in the display panel. The second electrode CE may include silver (Ag).

The second electrode CE may have the thickness C-TH of about 3 nm to about 5 nm.

A typical display panel includes a functional layer disposed on a second electrode. The functional layer includes indium zinc oxide (IZO) and is designed so that light provided from the display panel “resonates”. For example, it is designed so that the second electrode has a thickness of 2 nm and the functional layer has a thickness of 20 nm to 100 nm. However, when the display panel uses a resonance structure, a “white angular dependency (WAD)” phenomenon may occur according to a viewing angle. For example, a decrease in luminance of the display panel or color shift may occur according to the viewing angle.

In addition, when the functional layer is formed through a damage free sputter (DFS) process, a portion of the second electrode may be oxidized due to an oxygen gas condition and a high-temperature condition. Accordingly, reliability of the display panel may be decreased.

Referring to FIGS. 6 and 7, the display panel DP according to some example embodiments may include the functional layer FL having a significantly decreased thickness compared to the functional layer included in the typical display panel, thereby improving the light transmittance and reducing (and/or preventing) the occurrence of the “white angular dependency” phenomenon. The functional layer FL according to the inventive concepts may be also referred to as a “transparent conductive electrode (TCE)”.

Moreover, the functional layer FL included in the display panel DP according to some example embodiments may be formed through atomic layer deposition which may be performed at a relatively lower temperature without oxygen gas. Thus, damage to the second electrode CE may be reduced (and/or prevented).

In the display panel DP according to some example embodiments, the functional layer FL may be disposed on the second electrode CE. The functional layer FL may be directly disposed on the second electrode CE.

The functional layer FL may include titanium nitride (TiN).

The functional layer FL may have an electrically conductive property. The functional layer FL may be provided as a common layer, such that the functional layer FL is shared amongst each light emitting element OLED in the display panel.

The functional layer FL may have a light transmission property. Specifically, the functional layer FL may transmit about 60% or more of light in a visible light region.

In some example embodiments, the functional layer FL may have a thickness F-TH of greater than or equal to 2 nm and less than or equal to 6 nm.

The functional layer FL may be formed through an atomic layer deposition (ALD) process. This will be described later.

The capping layer CPL may be disposed on the functional layer FL. The capping layer CPL may be directly disposed on the functional layer FL.

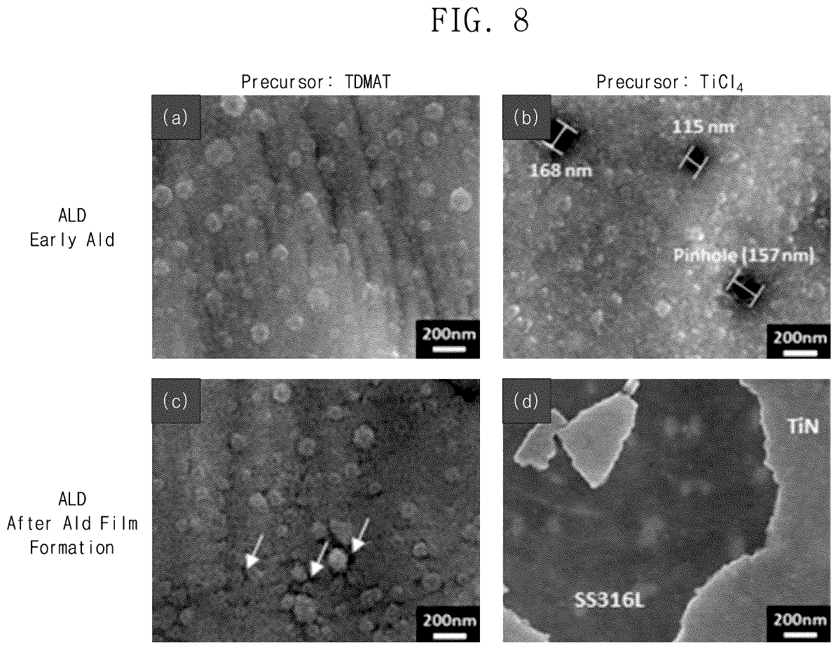

FIG. 8 is photographs showing film formation reliability of functional layers according to some example embodiments of the inventive concepts and a comparative example.

Photograph (a) is a photograph showing an early state in which film formation of titanium nitride (TiN) begins with an atomic layer deposition process under conditions in which TDMAT is a precursor. Photograph (c) is a photograph showing a state in which the film formation of titanium nitride (TiN) has been performed through the atomic layer deposition process under the conditions in which TDMAT is a precursor.

Photograph (b) is a photograph showing a state in which film formation of titanium nitride (TiN) begins with the atomic layer deposition process under conditions in which TiCl₄ is a precursor. Photograph (d) is a photograph showing a state in which the film formation of titanium nitride (TiN) has been performed through the atomic layer deposition process under the conditions in which TiCl₄ is a precursor.

Referring to photographs (a) and (b), a pin hole may be generated in the deposition process using TiCl₄ as a precursor. On the other hand, the pin hole may not be generated in the deposition process using TDMAT as a precursor.

Referring to photographs (c) and (d), a phenomenon may occur in which a portion of a deposition target is exposed by a crack occurring during the deposition process when using TiCl₄ as a precursor. On the other hand, it may be confirmed that, as described with reference to photograph (a), a substantially more uniform film formation process may be performed during the deposition process when using TDMAT as a precursor.

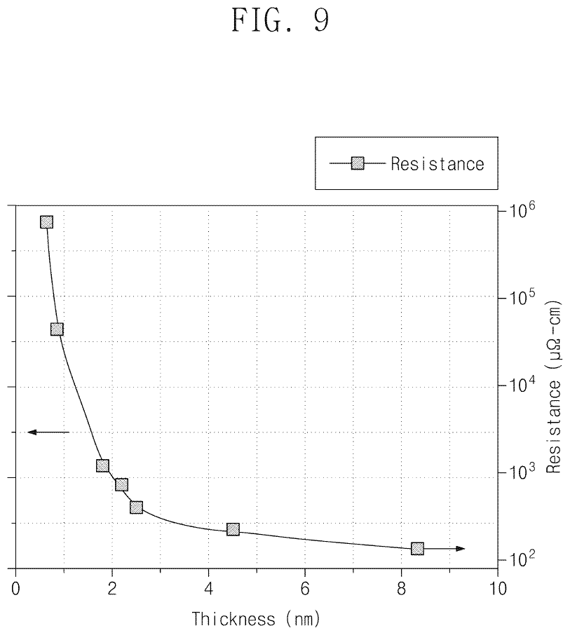

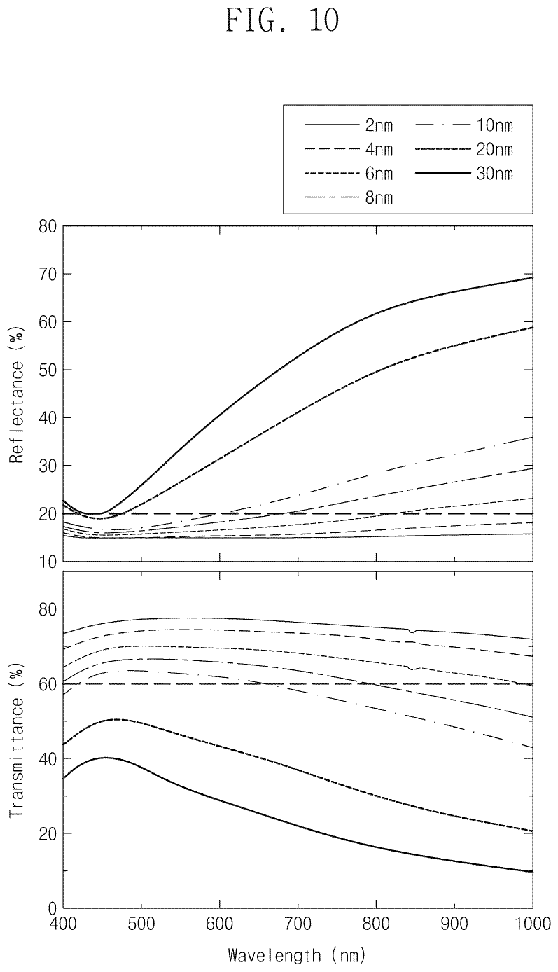

FIG. 9 is a graph illustrating experimental data according to some example embodiments of the inventive concepts. FIG. 10 is a graph illustrating experimental data according to some example embodiments of the inventive concepts.

FIG. 9 may be a graph illustrating a resistance change over a thickness F-TH of a functional layer FL.

Referring to FIG. 9, it may be ascertained that the functional layer FL has a relatively lower resistance value in a range in which the thickness F-TH of the functional layer FL is greater than or equal to 2 nm. However, when the thickness F-TH of the functional layer FL is less than or equal to 2 nm, the functional layer FL may show non-metallic behavior. That is, the resistance of the functional layer FL may be significantly increased in the range in which the thickness F-TH of the functional layer FL is less than or equal to 2 nm.

FIG. 10 may be a graph illustrating changes in reflectance and transmittance of light in a wavelength range of about 400 nm to about 1000 nm.

Referring to FIG. 10, it may be confirmed that when the thickness F-TH of the functional layer FL is greater than or equal to about 6 nm, the reflectance of the light is greater than or equal to 20% and the transmittance of the light is less than or equal to 60%.

Thus, when the experimental data in FIGS. 9 and 10 is put together, the thickness F-TH of the functional layer FL included in the display panel DP according to some example embodiments of the inventive concepts may be designed to be greater than or equal to 2 nm and less than or equal to 6 nm.

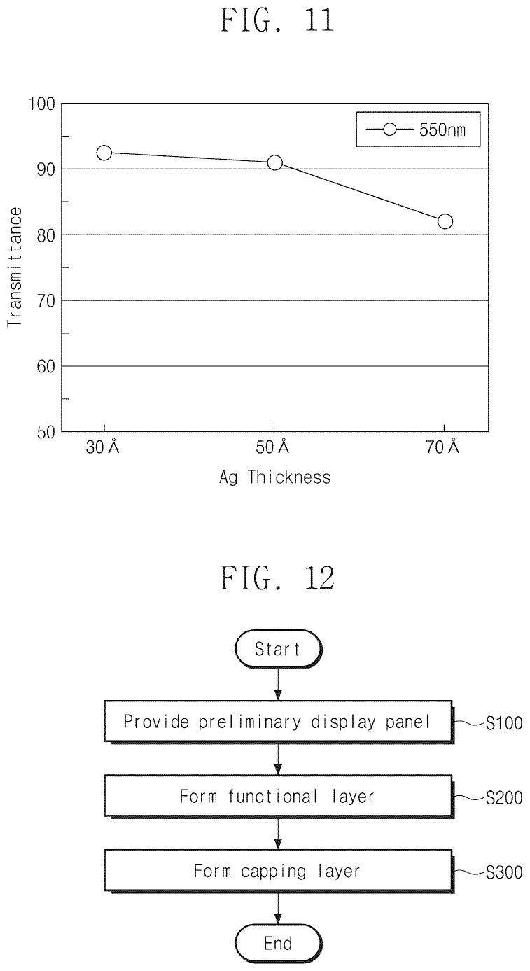

FIG. 11 is a graph illustrating experimental data according to some example embodiments of the inventive concepts.

FIG. 11 may be a view illustrating a light transmittance of a second electrode CE including silver (Ag).

Referring to FIG. 11, it may be ascertained that the second electrode CE has a high light transmittance of greater than or equal to 90% when a thickness C-TH of the second electrode CE is about 3 nm to about 5 nm.

It may be also ascertained that the light transmittance of the second electrode CE is significantly decreased when the thickness of the second electrode CE is greater than or equal to about 5 nm.

FIG. 12 is a flowchart of a method for manufacturing a display panel according to some example embodiments of the inventive concepts.

Referring to FIG. 12, the method for manufacturing the display panel according to some example embodiments of the inventive concepts may include steps of providing a preliminary display panel including a base layer, a first electrode disposed on the base layer, an emission layer disposed on the first electrode, and a second electrode disposed on the emission layer and having a thickness of about 3 nm to about 5 nm (S100), forming, on the second electrode, a functional layer including titanium nitride (TiN) and having a thickness of greater than or equal to 2 nm and less than or equal to 6 nm (S200), and forming a capping layer disposed on the functional layer (S300).

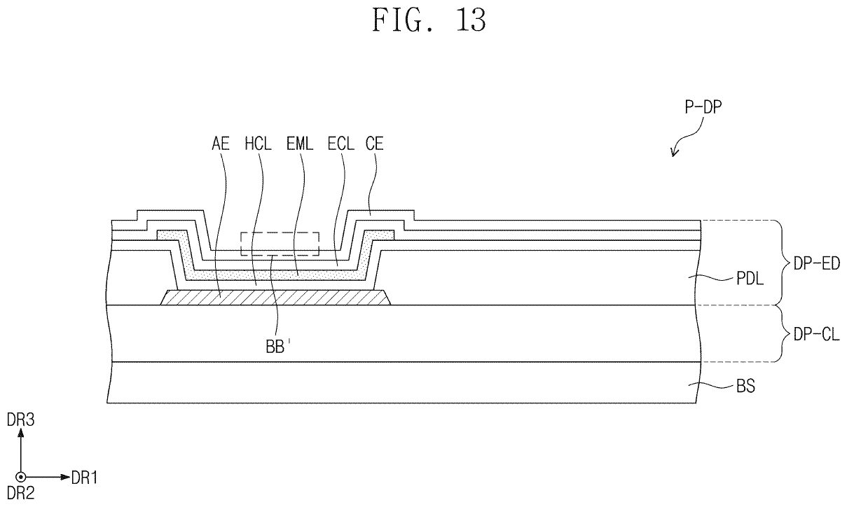

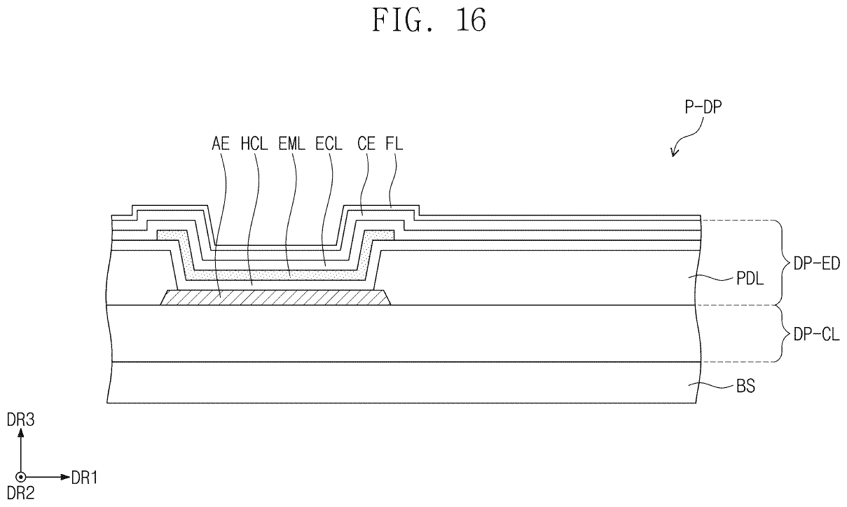

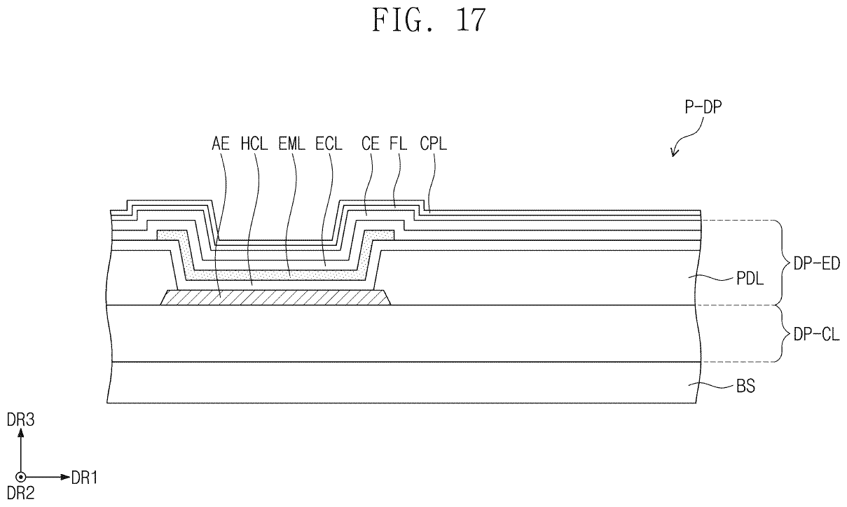

FIGS. 13 to 18 are each a view illustrating a step of a method for manufacturing a display panel according to some example embodiments of the inventive concepts.

As an example, FIG. 13 illustrates a state in which the step of providing the preliminary display panel (S100) has been performed. In the present disclosure, a “preliminary display panel P-DP” is placed during the manufacture of a display panel DP and may be used as a collective term for the display panel DP before completion.

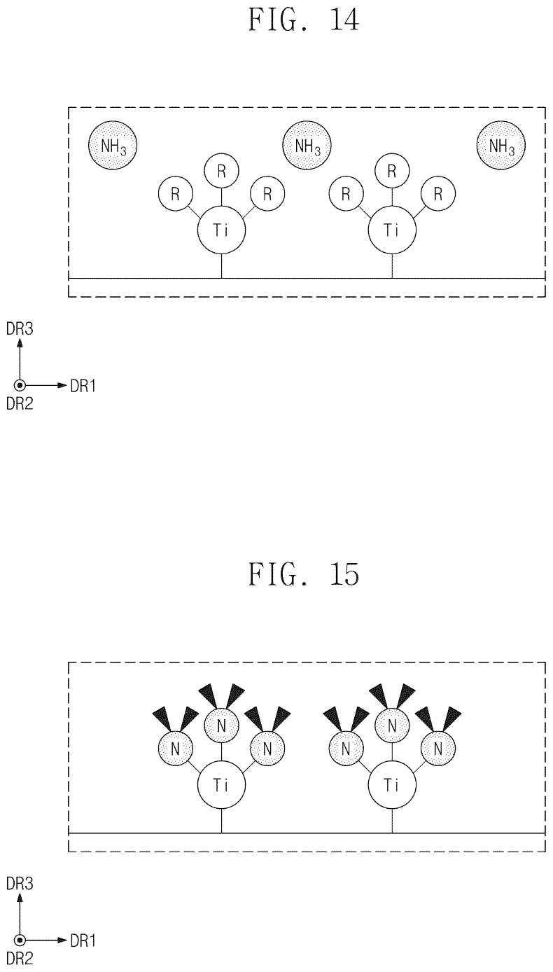

Thereafter, referring to FIGS. 14 to 16, the step of forming the functional layer (S200) may be performed.

The step of forming the functional layer (S200) may include performing film formation of titanium nitride (TiN) on a second electrode CE through an atomic layer deposition (ALD) process.

In this step, an oxygen gas may not be used in the atomic layer deposition process in order to reduce (and/or prevent) a phenomenon in which the second electrode CE is oxidized due to oxygen.

The atomic layer deposition process may be performed using an ammonia plasma (NH₃ plasma) and a precursor including tetrakis(alkylamido)titanium. Tetrakis(alkylamido)titanium may include at least one of tetrakis(dimethylamido)titanium (TDMAT), tetrakis(ethylmethylamido)titanium (TEMAT), or tetrakis(diethylamido)titanium (TDEAT).

FIG. 14 illustrates an example in which “tetrakis(alkylamido)titanium” that is a precursor is bound onto the second electrode CE. The ammonia plasma (NH₃) may be bound to titanium (Ti) instead of an “alkyl group (-R)” included in tetrakis(alkylamido)titanium, thereby achieving film formation of titanium nitride (TiN).

The step of forming the functional layer (S200) may be performed under a process temperature of about 30 °C to about to 70 °C. That is, the step of forming the functional layer (S200) may be carried out under a lower temperature condition than a chemical vapor deposition (CVD) process. Accordingly, an emission layer EML or the second electrode CE may be reduced (and/or prevented) from being thermally damaged.

Thereafter, referring to FIG. 17, the step of forming the capping layer on the functional layer (S300) may be performed. The capping layer CPL may be formed on the functional layer FL. The capping layer CPL may be directly formed on the functional layer FL. The capping layer CPL may be provided as a common layer.

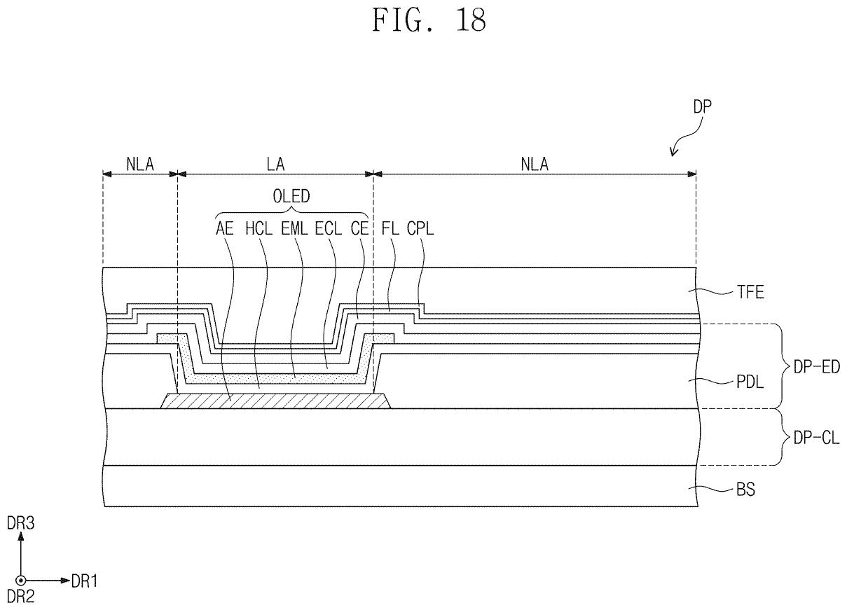

Thereafter, referring to FIG. 18, a step of forming an encapsulation layer TFE on the capping layer to complete the display panel DP may be performed. Although not separately illustrated, the encapsulation layer TFE may have a structure in which an inorganic layer and an organic layer are alternately stacked. The encapsulation layer TFE may function to reduce (and/or prevent) foreign matter such as moisture/oxygen from reaching a light emitting element OLED.

Some example embodiments of the inventive concepts may provide the display panel with the improved viewing angles and a decreased thickness, and a method for manufacturing the display panel.

Some example embodiments of the inventive concepts may also provide the display panel with the decreased damage to the electrode included in the light emitting element. Thus, a reliability of the display device may be increased.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

In the above, descriptions have been made with reference to example embodiments of the inventive concepts, but those skilled or of ordinary skill in the art may understand that various modifications and changes may be made to the inventive concepts insofar as such modifications and changes do not depart from the spirit and technical scope of the inventive concepts set forth in the claims to be described later. Therefore, the technical scope of the inventive concepts are not to be limited to the contents stated in the detailed description of the specification, but should be determined by the claims.

What is claimed is:

1. A display panel comprising:
a base layer; and
a display element layer on the base layer, the display element layer comprising
a first electrode,
an emission layer on the first electrode,
a second electrode on the emission layer, and
a functional layer on the second electrode,
wherein the functional layer comprises titanium nitride (TiN) and has a thickness greater than or equal to 2 nm and less than or equal to 6 nm, and
the second electrode has a thickness greater than or equal to 3 nm and less than or equal to 5 nm.

2. The display panel of claim 1, wherein the functional layer is directly contacting the second electrode.

3. The display panel of claim 1, wherein the functional layer is electrically conductive and has a light transmission property greater than or equal to 60% in a visible light region.

4. The display panel of claim 1, wherein the display element layer further comprises a capping layer on the functional layer.

5. The display panel of claim 4, wherein the capping layer is directly contacting the functional layer.

6. The display panel of claim 4, further comprising an encapsulation layer on the capping layer.

7. The display panel of claim 1, wherein the second electrode comprises silver (Ag).

8. The display panel of claim 1, further comprising:
a plurality of light emitting elements, and
a plurality of display element layers including the display element layer,
wherein
each of the plurality of display element layers are on the base layer,
each of the plurality of light emitting elements includes one of the plurality of display element layers, and
each of the second electrode of the display element layer and the functional layer of the display element layer are common to each of the plurality of light emitting elements.

9. A method for manufacturing a display panel, the method comprising:
providing a preliminary display panel comprising a base layer, a first electrode on the base layer, an emission layer on the first electrode, and a second electrode on the emission layer, the second electrode having a thickness of greater than or equal to 3 nm and less than or equal to 5 nm;
forming a functional layer on the second electrode, the functional layer comprising titanium nitride (TiN) and having a thickness greater than or equal to 2 nm and less than or equal to 6 nm; and
forming a capping layer on the functional layer.

10. The method of claim 9, wherein the forming of the functional layer comprises forming a titanium nitride layer using an atomic layer deposition (ALD) process.

11. The method of claim 10, wherein the ALD process includes an ammonia plasma and a precursor including tetrakis(alkylamido)titanium.

12. The method of claim 11, wherein tetrakis(alkylamido)titanium comprises at least one of tetrakis(dimethylamido)titanium, tetrakis(ethylmethylamido)titanium, or tetrakis(diethylamido)titanium.

13. The method of claim 9, wherein the forming of the functional layer is performed under a process temperature of 30 °C to 70 °C. 14. The method of claim 9, wherein the functional layer is directly contacting the second electrode.

15. The method of claim 9, wherein the functional layer is electrically conductive.

16. The method of claim 9, wherein the capping layer is directly contacting the functional layer.

17. The method of claim 9, wherein the functional layer has a light transmission property greater than or equal to 60% in a visible light region.

18. The method of claim 9, wherein the second electrode comprises silver (Ag).

19. An electronic device comprising:
a processor configured to provide image data; and
a display panel connected to the processor,
wherein the display panel comprises:
a base layer; and
a display element layer on the base layer, the display element layer comprising
a first electrode,
an emission layer on the first electrode,
a second electrode on the emission layer, and
a functional layer on the second electrode,
wherein the functional layer comprises titanium nitride (TiN) and has a thickness of greater than or equal to 2 nm and less than or equal to 6 nm, and
wherein the second electrode has a thickness of greater than or equal to 3 nm and less than or equal to 5 nm.

20. The electronic device of claim 19, wherein
the functional layer is directly contacting the second electrode and is electrically conductive, and
the electronic device further comprises a capping layer directly contacting the functional layer.
